(19) United States
(12) Patent Application Publication
(10) Pub. No.: US 2016/0335951 A1
(43) Pub. Date: Nov. 17, 2016

(54) SOURCE DRIVER AND OPERATING METHOD THEREOF

(71) Applicant: Raydium Semiconductor Corporation, Hsinchu (TW)

(72) Inventors: Tzong-Yau KU, Tainan City (TW); Jun-Ren SHIH, Hsinchu City (TW)

(21) Appl. No.: 15/041,148

(22) Filed: Feb. 11, 2016

Related U.S. Application Data
(60) Provisional application No. 62/162,269, filed on May 15, 2015.

(51) Int. Cl. G09G 3/20; G09G 3/36; H03M 1/66

(52) U.S. Cl. CPC G09G 3/2092; H03M 1/66; G09G 3/36

(57) ABSTRACT

A source driver applied in a display includes a DAC and an output buffer. The DAC receives M-bits digital input voltage and converts it into 2^{M} analog input voltages. M is a positive integer. The output buffer with interpolating function receives the 2^{M} analog input voltages and increases them to K analog output voltages in a N-bits interpolating way. N is a positive integer and K=2^{M}*2^{N}=2^{(M+N)}. The output buffer includes a positive output buffer unit and a negative output buffer unit and generates a positive interpolating voltage and a negative interpolating voltage through them respectively to share the same source output channel of the source driver and achieve linear interpolation voltage characteristics through mutual compensation between the positive interpolating voltage and the negative interpolating voltage.

### BACKGROUND OF THE INVENTION

1. Field of the Invention

This invention relates to a display apparatus, especially to a source driver and operating method thereof applied to a LCD apparatus.

2. Description of the Related Art

In general, if a source driving IC of a TFT-LCD panel wants to reach an output voltage of 100 bits, the conventional way is to generate 1024 voltages through a series of resistors and establish a 10 bits digital analog conversion circuit in each output channel, so that a corresponding voltage output can be selected from the 1024 voltages according to the digital input value.

It should be noticed that this operation needs 1024 voltages, that is to say, 1024 traces are necessary to connect all digital analog converters and a lot of chip area will be occupied. Therefore, an interpolating voltage generating circuit including the operating amplifier can be disposed in the source driving IC of the TFT-LCD panel to generate interpolating voltages. By doing so, only 64 voltages are generated by the series of resistors and then 16 voltages are generated by 4-bits interpolation of the operational amplifier; after multiplying, 1024 output voltages can be obtained but only 64 traces are necessary; therefore, the number of traces and the area occupied by the traces can be largely reduced.

However, when the source driving IC of the TFT-LCD panel generates 16 voltages by 4-bits interpolation of the operational amplifier, it is hard to reach ideal linear interpolation in circuit design, and there will be non-linear phenomenon of the interpolating voltage generated by the conventional operational amplifier as shown in FIG. 1. Obviously, it needs to be further improved.

### SUMMARY OF THE INVENTION

Therefore, the invention provides a source driver and operating method thereof to solve the above-mentioned problems.

An embodiment of the invention is a source driver. In this embodiment, the source driver is applied to a display apparatus. The source driver includes a digital analog converter (DAC) and an output buffer. The digital analog converter is configured to receive an M-bit digital input voltage and convert the M-bit digital input voltage into 2^{M} analog input voltages, wherein M is a positive integer. The output buffer having an interpolating function is coupled to the digital analog converter and configured to receive the 2^{M} analog input voltages and increase the 2^{M} analog input voltages to K analog output voltages in a N-bits interpolating way, wherein N is a positive integer and K=2^{M}*2^{N}=2^{(M+N)}. The output buffer includes a positive output buffer unit and a negative output buffer unit; the output buffer generates a positive interpolating voltage and a negative interpolating voltage through the positive output buffer unit and the negative output buffer unit respectively to share the same source output channel of the source driver and achieve a linear interpolation voltage characteristic through mutual compensation between the positive interpolating voltage and the negative interpolating voltage.

In an embodiment, a curve of the positive interpolating voltage corresponding to 2^{N} digital input code is a positive interpolating voltage output curve and a curve of the negative interpolating voltage corresponding to the 2^{N} digital input code is a negative interpolating voltage output curve.

In an embodiment, the positive output buffer unit and the negative output buffer unit have the same circuit size and wire connections, so that the positive interpolating voltage output curve and the negative interpolating voltage output curve are also the same.

In an embodiment, there is an offset of P digital input codes between the positive interpolating voltage output curve and the negative interpolating voltage output curve, and P is a positive integer.

In an embodiment, there is an offset of a specific voltage value between the positive interpolating voltage output curve and the negative interpolating voltage output curve.

In an embodiment, the positive interpolating voltage output curve and the negative interpolating voltage output curve are complementary to each other.

Another embodiment of the invention is a source driver operating method. In this embodiment, the source driver operating method is used for operating a source driver in a display apparatus. The source driver includes a digital analog converter (DAC) and an output buffer having an interpolating function. The source driver operating method includes the steps of: the digital analog converter receiving an M-bit digital input voltage and converting the M-bit digital input voltage into 2^{M} analog input voltages, wherein M is a positive integer; and the output buffer receiving the 2^{M} analog input voltages and increasing the 2^{M} analog input voltages to K analog output voltages in a N-bits interpolating way, wherein N is a positive integer and K=2^{M}*2^{N}=2^{(M+N)}. The output buffer includes a positive output buffer unit and a negative output buffer unit; the output buffer generates a positive interpolating voltage and a negative interpolating voltage through the positive output buffer unit and the negative output buffer unit respectively to share the same source output channel of the source driver and achieve a linear interpolation voltage characteristic through mutual compensation between the positive interpolating voltage and the negative interpolating voltage.

Compared to the prior art, the source driver and operating method thereof disclosed by the invention can achieve the following effects:

(1) since the operational amplifier is used to generate interpolating voltages, the number of traces can be largely decreased from 1024 to 64 and the area occupied by the traces can be also largely decreased;

(2) using the positive and negative polarities to generate the complementary interpolating voltages to realize ideal linear interpolating voltage characteristics; therefore, the non-linear interpolating voltage in the prior art can be effectively improved.

The advantage and spirit of the invention may be understood by the following detailed descriptions together with the appended drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic diagram of the non-linear phenomenon of the interpolating voltage generated by the conventional operational amplifier.

FIG. 2 illustrates schematic diagrams of the conventional non-linear interpolating voltage curve and the ideal linear interpolating voltage curve.

FIG. 3 illustrates a schematic diagram of the source driver in a preferred embodiment of the invention.

FIG. 4 illustrates schematic diagrams of the positive interpolating voltage output curve and the negative interpolating voltage output curve respectively.

FIG. 5 illustrates a schematic diagram of the negative interpolating voltage output curve generating an offset of digital input code relative to the positive interpolating voltage output curve.

FIG. 6 illustrates a schematic diagram of the negative interpolating voltage output curve generating offsets of digital input code and specific voltage value relative to the positive interpolating voltage output curve.

FIG. 7 illustrates a flowchart of the source driver operating method in a preferred embodiment of the invention.

### DETAILED DESCRIPTION

An aim of the invention is to improve the non-linear interpolating voltage generated by the operational amplifier in the source driver of the LCD display apparatus in the prior arts.

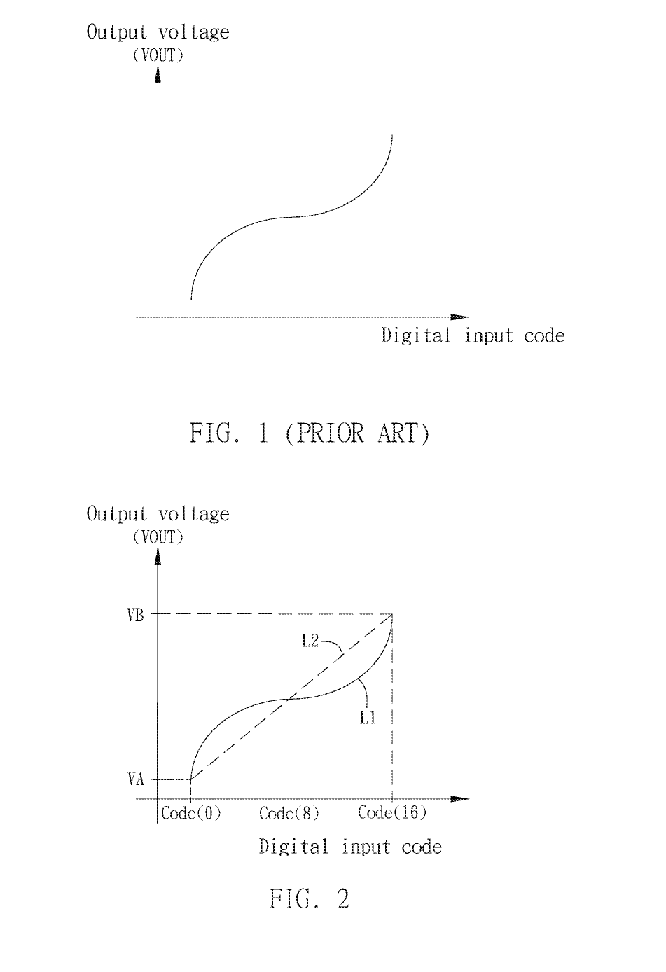

Please refer to FIG. 2. FIG. 2 illustrates schematic diagrams of the conventional non-linear interpolating voltage curve and the ideal linear interpolating voltage curve. As shown in FIG. 2, it is assumed that the solid line L1 in FIG. 2 represents the non-linear interpolating voltage curve generated by the operational amplifier in the conventional source driver and the dotted line L2 in FIG. 2 represents the ideal linear interpolating voltage curve.

Obviously, when the digital input code is Code (1)˜Code (7), the output voltage value corresponding to the non-linear interpolating voltage curve L1 will be larger than the output voltage value corresponding to the ideal linear interpolating voltage curve L2; when the digital input code is Code (9)˜Code (15), the output voltage value corresponding to the non-linear interpolating voltage curve L1 will be smaller than the output voltage value corresponding to the ideal linear interpolating voltage curve L2. Therefore, only when the digital input code is Code (8), the output voltage value corresponding to the non-linear interpolating voltage curve L1 will be equal to the output voltage value corresponding to the ideal linear interpolating voltage curve L2.

It is assumed that when the digital input code is Code (0), the output voltage value corresponding to the non-linear interpolating voltage curve L1 is VA and when the digital input code is Code (16), the output voltage value corresponding to the non-linear interpolating voltage curve L1 is VB, then when the digital input code is Code (8), the output voltage values corresponding to the non-linear interpolating voltage curve L1 and the ideal linear interpolating voltage curve L2 are both equal to 0.5*(VA+VB). Since there will be gamma setting voltages having positive and negative polarities on the driver of the LCD display apparatus, the invention use this theorem to use the positive and negative polarities to generate complementary interpolating voltages to achieve ideal linear interpolating voltage characteristics.

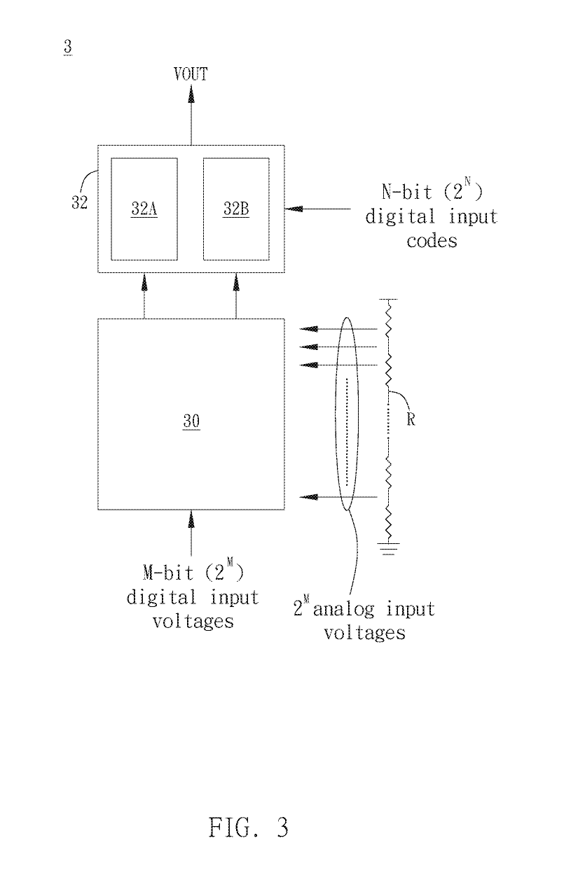

A preferred embodiment of the invention is a source driver. In this embodiment, the source driver is applied to a display apparatus. Please refer to FIG. 3. FIG. 3 illustrates a schematic diagram of the source driver in this embodiment.

As shown in FIG. 3, the source driver 3 includes a digital analog converter 30 and an output buffer 32. Wherein, the output buffer 32 has the interpolating function and it is coupled to the digital analog converter 30. The output buffer 32 includes a positive output buffer unit 32A and a negative output buffer unit 32B.

In this embodiment, it is assumed that the digital analog converter 30 receives M-bit digital input voltage (wherein M is a positive integer), the digital analog converter 30 will convert the M-bit digital input voltage into 2^{M} analog input voltages and then output the 2^{M} analog input voltages to the output buffer 32. In fact, as shown in FIG. 3, the source driver 3 also includes a series of resistors R and the series of resistors R is coupled to the digital analog converter 30 through 2^{M} traces. The series of resistors R generates 2^{M} analog input voltages to the digital analog converter 30 and then the digital analog converter 30 selects corresponding analog input voltage from the 2^{M} analog input voltages according to the M-bit digital input voltage respectively and outputs the corresponding analog input voltage.

When the output buffer 32 receives the 2^{M} analog input voltages, the output buffer 32 will increase the 2^{M} analog input voltages to K analog output voltages in a N-bits interpolating way, wherein N is a positive integer and K=2^{M}*2^{N}=2^{(M+N)}.

It should be noticed that the output buffer 32 will generate a positive interpolating voltage and a negative interpolating voltage through the positive output buffer unit 32A and the negative output buffer unit 32B respectively to share the same source output channel of the source driver 3 and achieve a linear interpolation voltage characteristic through mutual compensation between the positive interpolating voltage and the negative interpolating voltage.

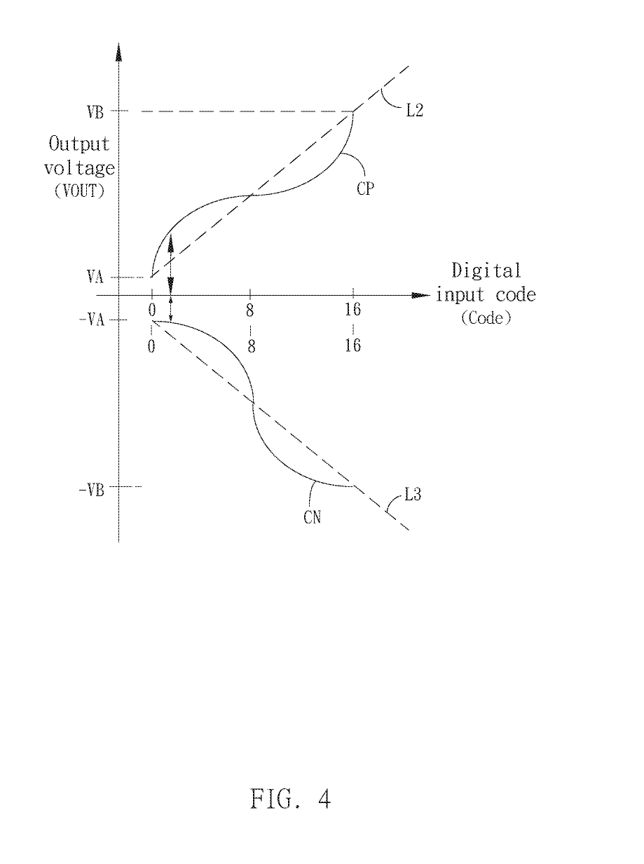

Then, please refer to FIG. 4. FIG. 4 illustrates schematic diagrams of the positive interpolating voltage output curve and the negative interpolating voltage output curve respectively.

As shown in FIG. 4, a curve of the positive interpolating voltage generated by the positive output buffer unit 32A corresponding to the 2^{N} digital input code is a positive interpolating voltage output curve CP and a curve of the negative interpolating voltage generated by the negative output buffer unit 32B corresponding to the 2^{N} digital input code is a negative interpolating voltage output curve CN. As to L2 and L3, L2 and L3 are ideal positive linear interpolating voltage and ideal negative linear interpolating voltage respectively.

It should be noticed that the positive interpolating voltage output curve CP and the negative interpolating voltage output curve CN are complementary to each other. For example, when the digital input code is Code (1), the output voltage corresponding to the positive interpolating voltage output curve CP and the output voltage corresponding to the negative interpolating voltage output curve CN are complementary to each other. At this time, the output voltage corresponding to the positive interpolating voltage output curve CP will be larger than the ideal positive interpolating voltage L2; therefore, its brightness is higher than the ideal brightness. However, the absolute value of the output voltage corresponding to the negative interpolating voltage output curve CN will be smaller than the ideal negative interpolating voltage L3, that is to say, the potential difference between the output voltage corresponding to the negative interpolating voltage output curve CN and the ground voltage will become smaller; therefore, its brightness is lower than the ideal brightness. Since one is lighter than the ideal brightness and the other is darker than the ideal brightness, after the mutual compensation between them, their brightness will approach the ideal linear effect.

In practical applications, the positive output buffer unit 32A and the negative output buffer unit 32B have the same circuit size and wire connections, so that the positive interpolating voltage output curve CP and the negative interpolating voltage output curve CN are also the same.

In an embodiment, there is an offset of P digital input codes between the positive interpolating voltage output curve CP and the negative interpolating voltage output curve CN, wherein P is a positive integer.

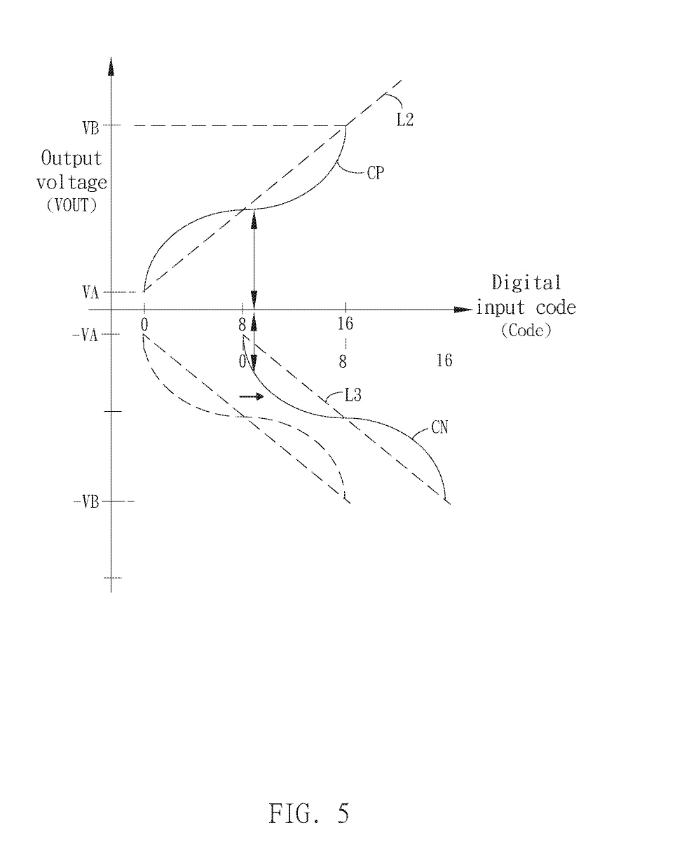

For example, as shown in FIG. 5, when the positive interpolating voltage output curve CP selects Code (K), the negative interpolating voltage output curve CN can select Code (K+8), wherein K is a positive integer. That is to say, there is an offset of 8 digital input codes between the positive interpolating voltage output curve CP and the negative interpolating voltage output curve CN at this time.

After the above-mentioned offsets, the positive interpolating voltage output curve CP and the negative interpolating voltage output curve CN are complementary to each other. For example, when the digital input code is Code (9), the output voltage corresponding to the positive interpolating voltage output curve CP will be smaller than the ideal positive interpolating voltage L2; therefore, its brightness is lower than the ideal brightness. However, the absolute value of the output voltage corresponding to the negative interpolating voltage output curve CN will be larger than the ideal negative interpolating voltage L3, that is to say, the potential difference between the output voltage corresponding to the negative interpolating voltage output curve CN and the ground voltage will become larger; therefore, its brightness is higher than the ideal brightness. Since one is lighter than the ideal brightness and the other is darker than the ideal brightness, after the mutual compensation between them, their brightness will approach the ideal linear effect.

Similarly, when the positive interpolating voltage output curve CP selects Code (K−4), the negative interpolating voltage output curve CN can select Code (K+4); therefore, there is an offset of 8 digital input codes between the positive interpolating voltage output curve CP and the negative interpolating voltage output curve CN at this time. When the positive interpolating voltage output curve CP selects Code (K+3), the negative interpolating voltage output curve CN can select Code (K−5); therefore, there is an offset of 8 digital input codes between the positive interpolating voltage output curve CP and the negative interpolating voltage output curve CN at this time. In practical applications, the above-mentioned offset can be generated by the positive interpolating voltage output curve CP or the negative interpolating voltage output curve CN alone or generated by both of the positive interpolating voltage output curve CP and the negative interpolating voltage output curve CN without any specific limitations and all included in the claims of the invention.

In another embodiment, there can be an offset of a specific voltage value ΔVS between the positive interpolating voltage output curve CP and the negative interpolating voltage output curve CN.

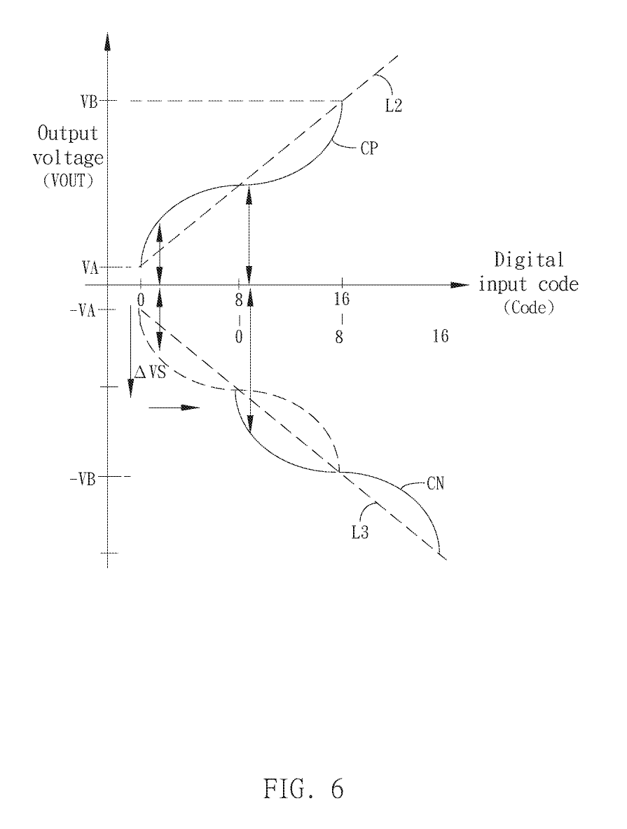

For example, as shown in FIG. 6, after the positive interpolating voltage output curve CP and the negative interpolating voltage output curve CN are relatively offset 8 digital input codes, the positive interpolating voltage output curve CP and the negative interpolating voltage output curve CN can also offset a specific voltage value ΔVS, so that the voltage value of the negative interpolating voltage output curve CN can be offset to the original corresponding voltage value.

After the above-mentioned offset of specific voltage value ΔVS, the positive interpolating voltage output curve CP and the negative interpolating voltage output curve CN are complementary to each other. For example, when the digital input code is Code (9), the output voltage corresponding to the positive interpolating voltage output curve CP will be smaller than the ideal positive interpolating voltage L2; therefore, its brightness is lower than the ideal brightness. However, the absolute value of the output voltage corresponding to the negative interpolating voltage output curve CN will be larger than the ideal negative interpolating voltage L3, that is to say, the potential difference between the output voltage corresponding to the negative interpolating voltage output curve CN and the ground voltage will become larger; therefore, its brightness is higher than the ideal brightness. Since one is lighter than the ideal brightness and the other is darker than the ideal brightness, after the mutual compensation between them, their brightness will approach the ideal linear effect.

It should be noticed that there is no limitations to the above-mentioned offset of specific voltage value ΔVS. In practical applications, the above-mentioned offset of specific voltage value ΔVS can be generated by the positive interpolating voltage output curve CP or the negative interpolating voltage output curve CN alone or generated by both of the positive interpolating voltage output curve CP and the negative interpolating voltage output curve CN without any specific limitations and all included in the claims of the invention.

In addition, the above-mentioned embodiments can be further expanded to any combinations. For example, a mapping table can be used to adjust the voltage values and/or digital input codes corresponding to the positive interpolating voltage output curve CP or the negative interpolating voltage output curve CN, so that the positive interpolating voltage output curve CP and the negative interpolating voltage output curve CN can be complementary to each other to achieve ideal linear interpolating voltage characteristics, or any other methods capable of making the brightness displayed approaching the ideal linear effects which are all included in the claims of the invention.

Another embodiment of the invention is a source driver operating method. In this embodiment, the source driver operating method is used for operating a source driver in a display apparatus. The source driver includes a digital analog converter (DAC) and an output buffer having an interpolating function. The output buffer includes a positive output buffer unit and a negative output buffer unit.

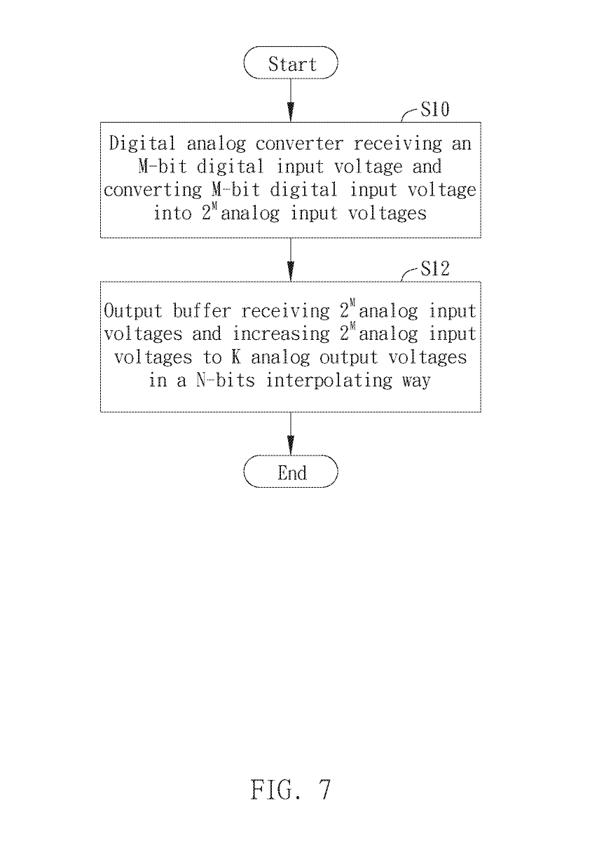

Please refer to FIG. 7. FIG. 7 illustrates a flowchart of the source driver operating method in this embodiment. As shown in FIG. 7, in the step S10, the digital analog converter receiving an M-bit digital input voltage and converting the M-bit digital input voltage into 2^{M} analog input voltages, wherein M is a positive integer. In the step S12, the output buffer receiving the 2^{M} analog input voltages and increasing the 2^{M} analog input voltages to K analog output voltages in a N-bits interpolating way, wherein N is a positive integer and K=2^{M}*2^{N}=2^{(M+N)}.

It should be noticed that the output buffer generates a positive interpolating voltage and a negative interpolating voltage through the positive output buffer unit and the negative output buffer unit respectively to share the same source output channel of the source driver and achieve a linear interpolation voltage characteristic through mutual compensation between the positive interpolating voltage and the negative interpolating voltage.

In practical applications, a curve of the positive interpolating voltage corresponding to 2^{N} digital input code (N-bit digital input code) is a positive interpolating voltage output curve and a curve of the negative interpolating voltage corresponding to the 2^{N} digital input code is a negative interpolating voltage output curve. The positive interpolating voltage output curve and the negative interpolating voltage output curve are complementary to each other.

Compared to the prior art, the source driver and operating method thereof disclosed by the invention can achieve the following effects:

(1) since the operational amplifier is used to generate interpolating voltages, the number of traces can be largely decreased from 1024 to 64 and the area occupied by the traces can be also largely decreased;

(2) using the positive and negative polarities to generate the complementary interpolating voltages to realize ideal linear interpolating voltage characteristics; therefore, the non-linear interpolating voltage in the prior art can be effectively improved.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. A source driver disposed in a display apparatus, the source driver comprising:
a digital analog converter (DAC) configured to receive an M-bit digital input voltage and convert the M-bit digital input voltage into 2^{M} analog input voltages, wherein M is a positive integer; and
an output buffer having an interpolating function being coupled to the digital analog converter and configured to receive the 2^{M} analog input voltages and increase the 2^{M} analog input voltages to K analog output voltages in a N-bits interpolating way, wherein N is a positive integer and K=2^{M}*2^{N}=2^{(M+N)};
wherein the output buffer comprises a positive output buffer unit and a negative output buffer unit; the output buffer generates a positive interpolating voltage and a negative interpolating voltage through the positive output buffer unit and the negative output buffer unit respectively to share the same source output channel of the source driver and achieve a linear interpolation voltage characteristic through mutual compensation between the positive interpolating voltage and the negative interpolating voltage.

2. The source driver of claim 1, wherein a curve of the positive interpolating voltage corresponding to 2^{N} digital input code is a positive interpolating voltage output curve and a curve of the negative interpolating voltage corresponding to the 2^{N} digital input code is a negative interpolating voltage output curve.

3. The source driver of claim 2, wherein the positive output buffer unit and the negative output buffer unit have the same circuit size and wire connections, so that the positive interpolating voltage output curve and the negative interpolating voltage output curve are also the same.

4. The source driver of claim 2, wherein there is an offset of P digital input codes between the positive interpolating voltage output curve and the negative interpolating voltage output curve, and P is a positive integer.

5. The source driver of claim 2, wherein there is an offset of a specific voltage value between the positive interpolating voltage output curve and the negative interpolating voltage output curve.

6. The source driver of claim 2, wherein the positive interpolating voltage output curve and the negative interpolating voltage output curve are complementary to each other.

7. A source driver operating method for operating a source driver in a display apparatus, the source driver comprising a digital analog converter (DAC) and an output buffer having an interpolating function, the source driver operating method comprising the steps of:
the digital analog converter receiving an M-bit digital input voltage and converting the M-bit digital input voltage into 2^{M} analog input voltages, wherein M is a positive integer; and
the output buffer receiving the 2^{M} analog input voltages and increasing the 2^{M} analog input voltages to K analog output voltages in a N-bits interpolating way, wherein N is a positive integer and K=2^{M}*2^{N}=2^{(M+N)};
wherein the output buffer comprises a positive output buffer unit and a negative output buffer unit; the output buffer generates a positive interpolating voltage and a negative interpolating voltage through the positive output buffer unit and the negative output buffer unit respectively to share the same source output channel of the source driver and achieve a linear interpolation voltage characteristic through mutual compensation between the positive interpolating voltage and the negative interpolating voltage.

8. The source driver operating method of claim 7, wherein a curve of the positive interpolating voltage corresponding to 2^{N} digital input code is a positive interpolating voltage output curve and a curve of the negative interpolating voltage corresponding to the 2^{N} digital input code is a negative interpolating voltage output curve.

9. The source driver operating method of claim 8, wherein the positive output buffer unit and the negative output buffer unit have the same circuit size and wire connections, so that the positive interpolating voltage output curve and the negative interpolating voltage output curve are also the same.

10. The source driver operating method of claim 8, wherein there is an offset of P digital input codes between the positive interpolating voltage output curve and the negative interpolating voltage output curve, and P is a positive integer.

11. The source driver operating method of claim 8, wherein there is an offset of a specific voltage value between the positive interpolating voltage output curve and the negative interpolating voltage output curve.

12. The source driver operating method of claim 8, wherein the positive interpolating voltage output curve and the negative interpolating voltage output curve are complementary to each other.
